(19) United States
(12) Patent Application Publication
(10) Pub. No.: US 2010/0233355 A1
(43) Pub. Date: Sep. 16, 2010

(54) Method of fabricating one-dimensional nanostructure of organo-optoelectronic material

(75) Inventors: Tu Lee, Flushing, NY (US); Ming-Shiou Lin, Meinong Town (TW)

Correspondence Address: Jackson Intellectual Property Group PLLC, 106 Starvale Lane, Shipman, VA, 22971, US

(73) Assignee: National Central University, Taoyuan County (TW)

(21) Appl. No.: 12/068,241

(22) Filed: Feb. 4, 2008

(30) Foreign Application Priority Data
Aug. 9, 2007 (TW) 096129462

(51) Int. Cl. B05D 5/12; B05D 5/06

(52) U.S. Cl. 427/58; 977/891

(57) ABSTRACT

An organo-optoelectronic nanowire is fabricated. It is made through a one-step unit operation under a low temperature. An organo-optoelectronic template is obtained for the fabrication, whose idea is a bio-inspired one. The nanowire obtained has a high efficiency and a high surface area; and, heat generated on operation is easily emitted. Thus, the present invention has a great potential for future use on optoelectronic devices.

### FIELD OF THE INVENTION

The present invention relates to fabricating an organo-optoelectronic nanowire; more particularly, relates to obtaining a nanowire with an organo-optoelectronic template through a one-step unit operation under a low temperature.

Description of the Related Arts

Organic electroluminescent devices are widely applicable with self-luminescence, wide view angle, saved power, low cost, high responsibility and full color gamut. And an organic electroluminescent material is critical for the device.

Methods for fabricating a nanowire of the organic electroluminescent material include chemical preparations, redox reactions, hydrothermal processes, spray-drying methods, sol-gel methods, emulsion methods, electrolysis methods and chemical vapor deposition (CVD) methods, where the CVD methods are the most widely used.

CVD obtains a film or tiny particles of a solid-state material with a gas or gases through a chemical reaction. A metal substrate is obtained, and a catalyst is coated on the substrate through ion sputtering with a powder of iron, aluminum or nickel. Therein, a plate is put in a horizontal tubular oven. Two refractories are obtained separately with the metal powder and the metal substrate put upon. The refractory with the metal powder is put at a co-current position corresponding to the refractory with the metal substrate. With an inert gas (like argon) filled-in, the metal substrate is prevented from oxidation. Then the horizontal tubular oven is heated to a high temperature to grow a metal material at a nano-scale. After the chemical reaction is finished, the temperature is lowered to a room temperature. Thus, a metal nanowire is obtained through CVD.

Although the prior arts fabricate nanowires, procedures related are complex, such as that both a substrate and a catalyst have to be prepared. Besides, their outputs are not effective enough and their costs are also high. Hence, the prior arts do not fulfill all users' requests on actual use.

### SUMMARY OF THE INVENTION

The main purpose of the present invention is to fabricate nanowires with an organo-optoelectronic template through a one-step unit operation under a low temperature.

To achieve the above purpose, the present invention is a method of fabricating a one-dimensional nanostructure of an organo-optoelectronic material, comprising steps of: (a) obtaining a fresh egg shell to be rinsed with a deionized water and, after being fully immersed in the deionized water for a period of time, removing a biological tissue from the egg shell to be vacuum-dried in a vacuum oven; (b) immersing a gold-coated wafer in an alcohol solution having 1-Undecanethiol (1-UDT) and 11-Mercaptoundecanoic acid (11-MUA) and taking out the wafer to be dried with a nitrogen gas for obtaining a self-assembly monolayer; and (c) obtaining a template comprised of the biological tissue and the self-assembly monolayer and spin cast films of soluble eggshell membrane solution processing a deposition on the template with powders of tris(8-hydroxyquinolato)aluminum (Alq3) or other organic compounds in an evaporation screening device under a controlled temperature to obtain an Alq3 nanowire, where the evaporation screening device comprises a ceramics hot plate as a heat source; an aluminum mass deposed on the ceramics hot plate, which has arrays of holes; a plurality of glass tubes inserted into the holes of the aluminum mass separately; and a plurality of stainless steel tubes inserted into the glass tubes separately. Accordingly, a novel method of fabricating a one-dimensional nanostructure of an organo-optoelectronic material is obtained.

### BRIEF DESCRIPTION OF THE DRAWING

The present invention will be better understood from the following detailed description of the preferred embodiment according to the present invention, taken in conjunction with the accompanying drawing, in which

FIG. 1 is the flow view showing the preferred embodiment according to the present invention.

### DESCRIPTION OF THE PREFERRED EMBODIMENT

The following description of the preferred embodiment is provided to understand the features and the structures of the present invention.

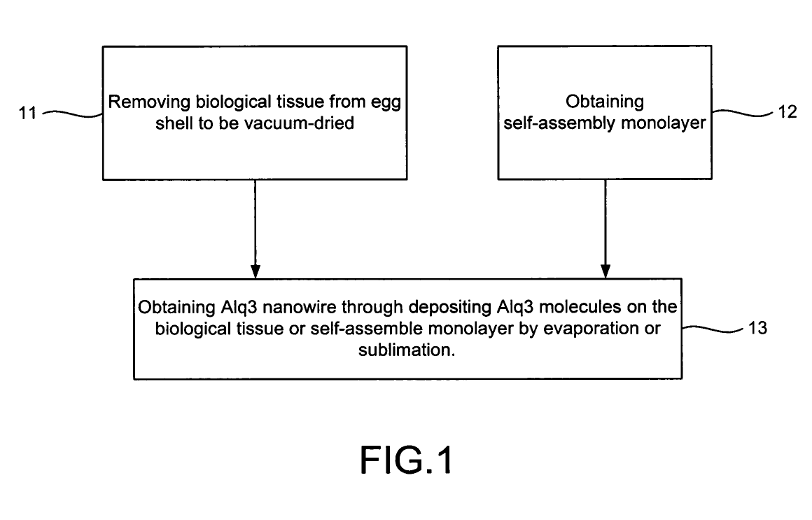

Please refer to FIG. 1, which is a flow view showing a preferred embodiment according to the present invention. As shown in the FIGURE, the present invention is a method of fabricating a one-dimensional nanostructure of an organo-optoelectronic material, comprising the following steps:

(a) Removing biological tissue from egg shell to be vacuum-dried 11: A fresh egg shell is obtained to be rinsed with deionized water and then is immersed in the deionized water half an hour. Then a biological tissue is removed from the egg shell into a vacuum oven and is vacuum-dried in the vacuum oven at 30 Celsius degrees (° C.) for 3 to 8 hours (hr), where the biological tissue is an egg membrane.

(b) Obtaining self-assembly monolayer 12: An alcohol solution having 1-Undecanethiol (1-UDT) and 11-Mercaptoundecanoic acid (11-MUA) is obtained, where the 1-UDT and the 11-MUA have a mole ratio of 1:1. A wafer coated with gold is immersed in the alcohol solution. After 48 hrs, the wafer is taken out to be dried with a nitrogen gas and thus a self-assembly monolayer is obtained.

(c) Obtaining Alq3 nanowire through hot-drying 13: A template comprised of the biological tissue and the self-assembly monolayer is processed through a deposition with a powder of tris(8-hydroxyquinolato)aluminum (Alq3) in an evaporation screening device under a controlled temperature of 280° C. half an hour with a vacuum of 6.7×10⁻² pascal to obtain an Alq3 nanowire. Therein, the Alq3 is a chelate of a hydroxyquinolinate and aluminum, which has a good electroluminescence; and, the Alq3 nanowire thus obtained is able to emit a green light having a range of wavelength around 530 nanometers (nm).

The evaporation screening device comprises a ceramics hot plate as a heat source; an aluminum mass on the ceramics hot plate, which has arrays of holes; a plurality of glass tubes inserted into the holes of the aluminum mass separately; and a plurality of stainless steel tubes inserted into the glass tube separately, each of which has a plate. And the evaporation screening device is connected with a vacuum pump. Thus, the evaporation screening device can be used to screen a few templates on a plurality of plates of the stainless steel tubes with a few materials evaporated.

On using the present invention, a one-step unit operation under a low temperature is used for fabricating the nanowire of an organo-optoelectronic material. Non-organic crystal may be found in living creature whose growth and arrangement are controlled through an organic layer. The present invention is thus inspired that the template of the organo-optoelectronic materials, comprising the biological tissue (i.e. egg membrane) and the self-assembly monolayer, is obtained for the Alq3 nanowire through a special group of the egg membrane. Therein, application of the self-assembly monolayer on the organic electroluminescent device increases efficiency and contact area; reduces destruction from humidity; and prolongs component stability and life time. And the induction of a conductive nano-structure is controlled and boundary of the nano-structure is screened.

Concerning the growth of the Alq3 nanowire, an X-ray electron spectrum for chemical analysis (ESCA) is used to analyze the self-assembly monolayer. Hence, it is proved that a compositive ratio on a wafer surface is selective and is not equal to a density ratio of the alcohol solution. Hence, the self-assembly monolayer simulates functional arrays to obtain a mechanism for growing nanowire. Besides, through a photoluminescence (PL) diagram of the Alq3 nanowire, it is found that the Alq3 nanowire has a higher strength and red-shift. Through a high efficiency and a high surface area, heat emission during operation can be enhanced. Hence, both with a low operating temperature and a one-step unit operation, the present invention is widely applicable.

To sum up, the present invention is a method of fabricating a one-dimensional nanostructure of an organo-optoelectronic material, where nanowires of an organo-optoelectronic material is fabricated through a one-step unit operation with a bio-inspired template; through a high efficiency and a high surface area, heat emission generated on operation is enhanced; and, both with a low operating temperature and a one-step unit operation, the present invention is widely applicable.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

What is claimed is:

1. A method of fabricating a one-dimensional nanostructure of an organo-optoelectronic material, comprising steps of:
(a) obtaining a fresh egg shell to be washed with a deionized water and, after being fully immersed in said deionized water for a period of time, removing a biological tissue from said egg shell to be vacuum-dried in a vacuum oven;
(b) immersing a gold-coated wafer in an alcohol solution having 1-Undecanethiol (1-UDT) and 11-Mercaptoundecanoic acid (11-MUA) and taking out said wafer to obtain a self-assembly monolayer by being dried with a nitrogen gas; and
(c) obtaining a template comprised of said biological tissue and said self-assembly monolayer and processing a deposition on said template with a powder of tris(8-hydroxyquinolato)aluminum(III) (Alq3) in an evaporation screening device under a controlled temperature to obtain an Alq3 nanowire.

2. The method according to claim 1,
wherein said egg shell is immersed in said deionized water half an hour.

3. The method according to claim 1,
wherein said biological tissue is an egg membrane.

4. The method according to claim 1,
wherein said biological tissue is dried in said vacuum oven under a temperature of 30 Celsius degrees (° C.) for 3 to 8 hours (hr).

5. The method according to claim 1,
wherein said 1-UDT and said 11-MUA have a mole ratio of 1:1.

6. The method according to claim 1,
wherein said wafer is immersed for 48 hrs.

7. The method according to claim 1,
wherein said deposition in said evaporation screening device is processed half an hour under 280° C. with a vacuum of 6.7×10⁻² pascal.

8. The method according to claim 1,
wherein said controlled temperature is 60° C.

9. The method according to claim 1,
wherein said evaporation screening device comprises:
a ceramics hot plate, said ceramics hot plate being a heat source;
an aluminum mass, said aluminum mass being deposed on said ceramics hot plate, said aluminum mass having holes;
a plurality of glass tubes, said glass tube being inserted into said hole of said aluminum mass; and
a plurality of stainless steel tubes, said stainless steel tube being inserted into said glass tube.

10. The method according to claim 9,
wherein said stainless steel tube is hollow.

11. The method according to claim 9,
wherein said stainless steel tube has a plate.

12. The method according to claim 9,
wherein said evaporation screening device is connected with a vacuum pump.
